(19) United States
(12) Patent Application Publication
(10) Pub. No.: US 2021/0074306 A1
(43) Pub. Date: Mar. 11, 2021

(54) ENCODING METHOD AND DECODING METHOD FOR AUDIO SIGNAL USING DYNAMIC MODEL PARAMETER, AUDIO ENCODING APPARATUS AND AUDIO DECODING APPARATUS

(71) Applicant: Electronics and Telecommunications Research Institute, Daejeon (KR)

(72) Inventors: Jongmo SUNG, Daejeon (KR); Seung Kwon BEACK, Daejeon (KR); Mi Suk LEE, Daejeon (KR); Tae Jin LEE, Daejeon (KR); Woo-taek LIM, Daejeon (KR); Jin Soo CHOI, Daejeon (KR)

(73) Assignee: Electronics and Telecommunications Research Institute, Daejeon (KR)

(21) Appl. No.: 17/017,413

(22) Filed: Sep. 10, 2020

(30) Foreign Application Priority Data
Sep. 10, 2019 (KR) 10-2019-0112153
Sep. 9, 2020 (KR) 10-2020-0115530

(51) Int. Cl. G10L 19/032; H03M 7/30; G06N 3/08; G06N 5/04

(52) U.S. Cl. CPC G10L 19/032; H03M 7/6011; G06N 5/046; G06N 3/084; H03M 7/6005

(57) ABSTRACT

Provided are an audio encoding method, an audio decoding method, an audio encoding apparatus, and an audio decoding apparatus using dynamic model parameters. The audio encoding method using dynamic model parameters may use dynamic model parameters corresponding to each of the levels of the encoding network when reducing the dimension of an audio signal in the encoding network. In addition, the audio decoding method using the dynamic model parameter may use a dynamic model parameter corresponding to each of the levels of the decoding network when extending the dimension of an audio signal in an encoding network.

### CROSS-REFERENCE TO RELATED APPLICATIONS

This application claims the priority benefit of Korean Patent Application No. 10-2019-0112153 filed on Sep. 10, 2019 and Korean Patent Application No. 10-2020-0115530 filed on Sep. 9, 2020 in the Korean Intellectual Property Office, the disclosures of which are incorporated herein by reference for all purposes.

### BACKGROUND

### 1. Field

One or more example embodiments relate to an audio encoding method and an audio decoding method, an audio encoding apparatus and an audio decoding apparatus using dynamic model parameters, and more specifically, to generating dynamic model parameters in all layers of an encoding network and a decoding network.

### 2. Description of Related Art

Due to the recent development of deep learning technology, various deep learning technologies are being used to process voice, audio, language and video. In particular, in order to process audio signals, deep learning technology is actively used. When encoding or decoding an audio signal, a method for efficiently encoding or decoding an audio signal by using a neural network such as a network composed of a plurality of layers is also proposed.

### SUMMARY

According to an aspect, there is provided an audio encoding method using a dynamic model parameter, comprising: reducing a dimension of audio signal using an encoding network; outputting a code corresponding to audio signal of a final level whose the dimension is reduced; and quantizing the code, wherein the outputting the code reduces the dimension of the audio signal corresponding to a plurality of layers of N level by using a dynamic model parameter of each of the layers of the encoding network.

The dynamic model parameter is generated for the layers corresponding to N−1 level in all N level.

The dynamic model parameter is determined in a dynamic model parameter generation network independent of the encoding network.

The dynamic model parameter is determined based on a feature of a previous level to determine the feature of a next level.

The encoding network determines a feature for the audio signal of a next level using a feature for the audio signal of a previous level and the dynamic model parameter of the next level, wherein the feature for the audio signal of the next level is a signal whose dimension is reduced than the feature for the audio signal of the previous level.

According to an aspect, there is provided an audio decoding method using a dynamic model parameter, comprising: receiving a quantized code of an audio signal corresponding to a reduced dimension; extending the dimension of the audio signal in a decoding network by using the code of the audio signal; outputting the audio signal of a final level with an expanded dimension in the decoding network, wherein the extending the dimension of the audio signal extends the dimension of the audio signal corresponding to the layer of N levels by using a dynamic model parameter of each of the levels of the decoding network.

The dynamic model parameter is generated for the layers corresponding to N−1 level in all N level.

The dynamic model parameter is determined in a dynamic model parameter generation network independent of the encoding network.

The dynamic model parameter is determined based on a feature of a previous level to determine the feature of a next level.

The decoding network determines a feature for the audio signal of a next level using a feature for the audio signal of a previous level and the dynamic model parameter of the next level, wherein the feature for the audio signal of the next level is a signal whose dimension is extended than the feature for the audio signal of the previous level.

According to another aspect, there is also provided an audio encoding method using a dynamic model parameter, comprising: reducing a dimension of audio signal using an encoding network; outputting a code corresponding to audio signal of a final level whose the dimension is reduced; and quantizing the code, wherein the outputting the code reduces the dimension of the audio signal corresponding to a plurality of layers of N level by using a dynamic model parameter of at least one of specific layer among the layers of the encoding network.

The outputting the code reduces the dimension of the audio signal is reduced using dynamic model parameters at the specific level of the encoding network, and reduces the dimension of the audio signal using static model parameters at a remaining levels except for the specific level among all levels of the encoding network.

The dynamic model parameter is determined in a dynamic model parameter generation network independent of the encoding network.

The dynamic model parameter is determined based on a feature of a previous level to determine the feature of a next level.

The encoding network determines a feature for the audio signal of a next level using a feature for the audio signal of a previous level and the dynamic model parameter of the next level, wherein the feature for the audio signal of the next level is a signal whose dimension is reduced than the feature for the audio signal of the previous level.

According to another aspect, there is also provided an audio decoding method using a dynamic model parameter, comprising: receiving a quantized code of an audio signal corresponding to a reduced dimension; extending the dimension of the audio signal in a decoding network by using the code of the audio signal; outputting the audio signal of a final level with an expanded dimension in the decoding network, wherein the extending the dimension extends the dimension of the audio signal corresponding to a plurality of layers of N level by using a dynamic model parameter of at least one of specific layer among the layers of the encoding network.

The extending the dimension extends the dimension of the audio signal is reduced using dynamic model parameters at the specific level of the encoding network, and extends the dimension of the audio signal using static model parameters at a remaining levels except for the specific level among all levels of the encoding network.

The dynamic model parameter is determined in a dynamic model parameter generation network independent of the encoding network.

The dynamic model parameter is determined based on a feature of a previous level to determine the feature of a next level.

The decoding network determines a feature for the audio signal of a next level using a feature for the audio signal of a previous level and the dynamic model parameter or a static model parameter of the next level, wherein the feature for the audio signal of the next level is a signal whose dimension is extended than the feature for the audio signal of the previous level.

Additional aspects of example embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 illustrates a detailed network of an auto encoder for encoding and decoding an audio signal according to an embodiment of the present invention;

FIG. 2 illustrates an audio encoding method according to an embodiment of the present invention;

FIG. 3 is a flowchart illustrating an audio decoding method according to an embodiment of the present invention;

FIG. 4 is a flowchart illustrating an audio encoding method and an audio decoding method according to an embodiment of the present invention;

FIG. 5 illustrates an audio encoding method and an audio decoding method according to another embodiment of the present invention;

FIG. 6 illustrates a process of deriving a dynamic model parameter for each layer of an auto encoder according to an embodiment of the present invention;

FIG. 7 illustrates a process of deriving dynamic model parameters for a specific layer of an auto encoder according to another embodiment of the present invention.

### DETAILED DESCRIPTION

Hereinafter, reference will now be made in detail to example embodiments with reference to the accompanying drawings, wherein like reference numerals refer to like elements throughout. However, the scope of the disclosure is not limited by those example embodiments.

The terms used herein are mainly selected from general terms currently being used in related art(s). However, other terms may be used depending on development and/or changes in technology, custom, or a preference of an operator. Thus, it should be understood that the terms used herein are terms merely used to describe the example embodiments, rather terms intended to limit the spirit and scope of this disclosure.

In addition, in a specific case, most appropriate terms have been arbitrarily selected by the inventors for ease of description and/or for ease of understanding. In this instance, the meanings of the arbitrarily used terms will be clearly explained in the corresponding description. Hence, the terms should be understood not by the simple names of the terms, but by the meanings of the terms and the following overall description of this specification.

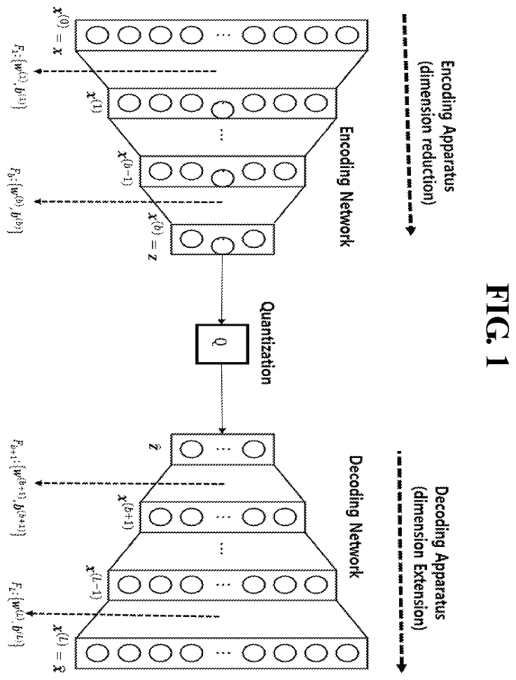

FIG. 1 illustrates a detailed network of an auto encoder for encoding and decoding an audio signal according to an embodiment of the present invention;

In the present invention, a deep autoencoder consisting of a plurality of layers may be used as a network structure for encoding or decoding an audio signal. Autoencoder has a representative deep learning structure for dimensionality reduction and representation learning. The deep-auto encoder may be composed of layers corresponding to each of a plurality of levels and has a neural network that makes the input layer and the output layer the same. In the present invention, the deep autoencoder may be composed of an encoding network and a decoding network as shown in FIG. 1.

FIG. 1 shows the basic structure of a deep auto encoder. In the encoding process of the deep auto encoder, the encoding network encodes the audio signal in a manner that reduces the dimension compared to the input layer. Code Z is derived from the last layer of the encoding network.

When the input data is high-dimensional (that is, the number of variables is large) and it is difficult to express the relationship between variables (or features), it is a low-dimensional vector that is easy to process while properly expressing the features of the data. Can be converted. The code refers to a new variable obtained by converting variables (or features) of the audio signal. In addition, the output value of the deep auto-encoder is a predicted value of the deep auto-encoder, and the decoding network is learned such that the audio signal input to the deep auto-encoder and the audio signal restored through the deep auto-encoder are identical to each other. Here, the code may be expressed as a latent variable. In addition, the decoding process of the deep auto encoder restores the audio signal by extending the dimension. Layers constituting the deep auto encoder may be referred to as a hidden layer, and a hidden layer for encoding and a hidden layer for decoding may be configured to be symmetric with each other.

The audio signal input to the encoding network may be reduced in dimension through a plurality of layers constituting the encoding network of the deep auto encoder and may be expressed as a latent vector of the hidden layer. In addition, the latent vector of the hidden layer is dimensionally extended through a plurality of layers constituting a decoding network of the deep auto encoder, so that an audio signal that is substantially identical to an audio signal input to the encoding network may be restored.

The number of layers constituting the encoding network and the number of layers constituting the decoding network may be the same or different from each other. In this case, if the number of layers constituting the encoding network and the decoding network is the same, the encoding network and the decoding network have a structure symmetrical to each other.

According to an embodiment of the present invention, an audio signal input to an encoding network is output as a code with a reduced dimension through a plurality of layers constituting an encoding network of a deep-auto encoder. In addition, the code is reconstructed as an audio signal by extending the dimension through a plurality of layers constituting the decoding network of the deep autoencoder. In this case, a parameter for minimizing the error function of the deep auto encoder may be determined through a learning process so that the audio signal input to the encoding network and the audio signal restored through the decoding network are substantially the same.

The network structure of the deep auto encoder represents a structure such as a fully-connected (FC) or a convolutional neural network (CNN), but the present invention is not limited thereto, and any type composed of a plurality of layers may be used.

The meaning of the variables shown in FIG. 1 is as follows.

x: Audio signal input to the encoding network

x⁽ⁱ⁾: feature of i-th layer

z: Latent vector (or code, bottleneck)

\hat{z}: Quantized code

\hat{x}: Audio signal restored through the decoding network

i: Index of Layer

{w⁽ⁱ⁾,b⁽ⁱ⁾}: Dynamic model parameters of the i-th layer

b: Index of Layer for code

L: Total number of layers that make up the autoencoder's network

Q: Quantization

In FIG. 1, the output value of the ith layer is x⁽ⁱ⁾=Fᵢ(x⁽ⁱ⁻¹⁾)=σ({w⁽ⁱ⁾}^{T}·x⁽ⁱ⁻¹⁾+b⁽ⁱ⁾). In this case, where x⁽⁰⁾=x, σ(⋅) represents a nonlinear activation function.

According to an embodiment of the present invention, the feed-forward process of an autoencoder is as follows.

Encoding process: z=x^{(b)}=F_{b}∘F_{b-1}∘ . . . F₁(x)

Quantization: \hat{z}=Q(z)

Decryption process: \hat{x}=x^{(L)}=F_{L}∘F_{L-1}∘ F_{b+1}(\hat{z}) where F∘G(x)=F(G(x))

In addition, according to an embodiment of the present invention, the learning process of the autoencoder is as follows.

Loss function: [symbol] (x, \hat{x}; F₁, F₂, . . . , F_{L})

The loss function L is an objective function and may be expressed as a weighted sum such as a Mean-Squared Error (MSE) and a bit rate that determine the encoding and decoding performance of the autoencoder. The basic purpose of an autoencoder is to make the audio signal input to the encoding network of the autoencoder almost identical to the audio signal restored through the decoding network of the autoencoder.

In order to determine the dynamic model parameters {w⁽ⁱ⁾, b⁽ⁱ⁾} of the i-th layer and quantization parameters (eg, codebook), Each dynamic model parameter can be updated by back-propagation of the loss function determined by the audio signal \hat{x} restored through the feed-forward process and the audio signal x input to the autoencoder, from the output layer to the input layer. To this end, the process of quantizing the code z may be proceed in a form that can be differentiated in the learning stage.

Static model parameters obtained through a conventional learning process frequently occur over-fitting or under-fitting to a DB for training. Simply, the static model parameters obtained through learning are commonly applied regardless of a characteristic of audio signal input to the autoencoder. Therefore, the conventional static model parameters are very limited in reflecting the characteristics of various audio signals. Accordingly, even when a wide variety of audio signals are input, an encoding/decoding process that can reflect the characteristics of the audio signal is required.

The present invention proposes a method of dynamically deriving dynamic model parameters from a plurality of layers constituting a deep auto encoder to reflect the characteristics of an audio signal based on the deep auto encoder.

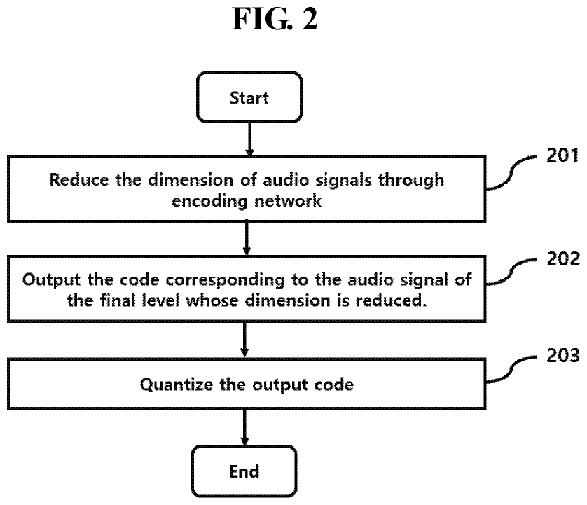

FIG. 2 illustrates an audio encoding method according to an embodiment of the present invention;

The audio encoding method of FIG. 2 may be performed by an audio encoding apparatus.

In step 201 of FIG. 2, the audio encoding apparatus may reduce the dimension of the audio signal through a plurality of encoding networks. Also, the audio encoding apparatus may reduce the dimension of a feature for the audio signal.

In step 202 of FIG. 2, the audio encoding apparatus may output a code corresponding to the audio signal of the final layer whose dimension is reduced in the encoding network. Here, the audio encoding apparatus may reduce the dimension of the audio signal corresponding to the layers of the N levels by using the dynamic model parameter of each of the layers of the encoding network. Dynamic model parameters may be generated for N−1 level for N levels in the encoding network.

The dynamic model parameter may be determined in a dynamic model parameter generation network independent from the encoding network. And, the dynamic model parameter may be determined based on the feature of the previous level to determine the feature of the next level. The encoding network may determine a feature for the audio signal of a next level using a feature for the audio signal of a previous level and the dynamic model parameter of the next level. The feature for the audio signal of the next level is a signal whose dimension is reduced than the feature for the audio signal of the previous level.

In step 203 of FIG. 2, the audio encoding apparatus may quantize the output code.

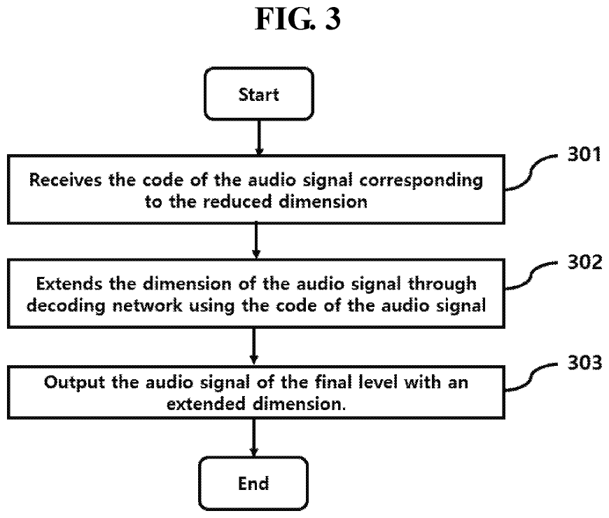

FIG. 3 is a flowchart illustrating an audio decoding method according to an embodiment of the present invention;

The audio decoding method of FIG. 3 may be performed by an audio decoding apparatus.

In step 301 of FIG. 3, the audio decoding method may receive a quantized code of an audio signal corresponding to a reduced dimension.

In step 302 of FIG. 3, the audio decoding method may extend the dimension of the audio signal through a plurality of decoding networks using the code of the audio signal. Also, the audio decoding apparatus may extend the dimension of a feature for the audio signal. The audio decoding apparatus may extend the dimension of the audio signal corresponding to the layers of the N levels by using the dynamic model parameter of each of the layers of the decoding network. The audio decoding apparatus may extend the dimension of the feature for the audio signal corresponding to the layers of the N levels by using the dynamic model parameter of each of the layers of the decoding network.

Here, the audio decoding apparatus may extend the dimension of the audio signal corresponding to the layers of the N levels by using the dynamic model parameter of each of the layers of the decoding network. Dynamic model parameters may be generated for N−1 levels for N levels in the decoding network.

The dynamic model parameter may be determined in a dynamic model parameter generation network independent from the decoding network. And the dynamic model parameter may be determined based on the feature of the previous level to determine the feature of the next level. The decoding network may determine a feature for the audio signal of a next level using a feature for the audio signal of a previous level and the dynamic model parameter of the next level. The feature for the audio signal of the next level is a signal whose dimension is extended than the feature for the audio signal of the previous level.

In step 303 of FIG. 3, the audio decoding method may output an audio signal of a final level whose dimension is extended in the decoding network.

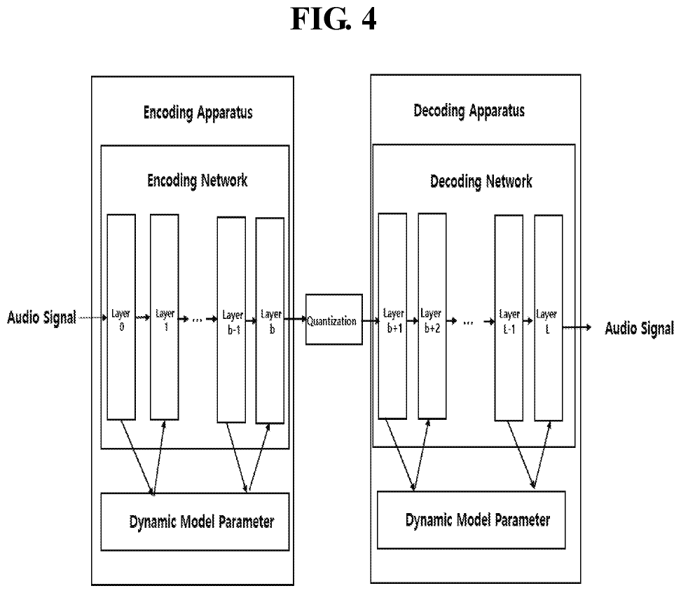

FIG. 4 is a flowchart illustrating an audio encoding method and an audio decoding method according to an embodiment of the present invention;

In the case of FIG. 4, a process of generating a dynamic model parameter for all of the encoding process that is the first audio signal processing method and the decoding process that is the second audio signal processing method is shown.

As shown in FIG. 4, it is assumed that the encoding network for reducing the dimension of an audio signal in the deep-auto encoder is composed of layer 0 to layer b corresponding to levels, and that the decoding network extending the dimension is composed of layer b+1 to layer L corresponding to levels. Then, the encoding device may reduce the dimension of the audio signal by using the encoding network. And, the result of the reduced dimension can be quantized as a code.

In this case, according to an embodiment of the present invention, a dynamic model parameter may be generated for each layer of an encoding network. The layer corresponds to levels of the encoding network. Specifically, the feature of the i-th layer (current layer) are determined based on the feature of the i−1th layer (previous layer) and the dynamic model parameters of the i th layer (next layer). In a similar manner, the feature of the i+1th layer (next layer) are determined based on the dynamic model parameters of i+1th level and the feature of the ith layer (current layer). That is, the process of generating the dynamic model parameter may determine a dynamic model parameter for deriving a feature of a current layer from a feature derived from a previous layer.

In particular, in FIG. 4, dynamic model parameters may be applied to all layers of a network for processing a first audio signal for encoding and processing a second audio signal for decoding. However, the dynamic model parameter generation network may be independently applied to the encoding process and the decoding process.

Dynamic model parameters of each of the layers may be determined based on features of each of the plurality of layers. That is, according to an embodiment of the present invention, for audio encoding based on a deep-auto encoder, a model parameter of an autoencoder is dynamically calculated based on the feature of each of a plurality of layers constituting the autoencoder, thereby The quality for the restoration of can be improved.

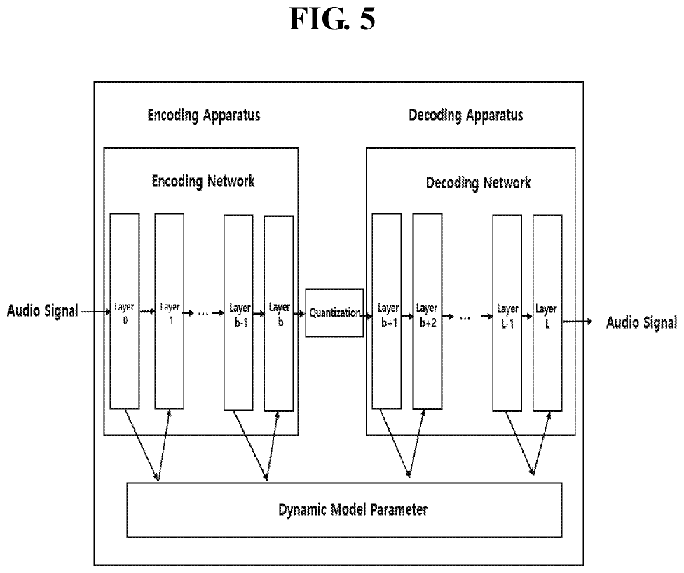

FIG. 5 illustrates an audio encoding method and an audio decoding method according to another embodiment of the present invention;

In FIG. 5, unlike FIG. 4, a dynamic model parameter may be commonly generated for an encoding process, which is a first audio signal processing method, and a decoding process, which is a second audio signal processing method. That is, the dynamic model parameter generation network can be applied in common to each other for an encoding process and a decoding process. Like FIG. 4, a dynamic model parameter may be generated for each layer for encoding an audio signal, and a dynamic model parameter may be generated for each layer for decoding an audio signal.

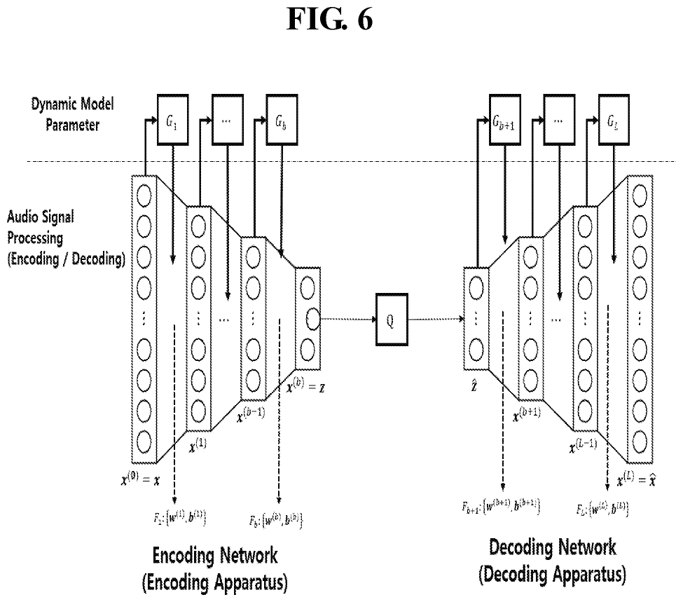

FIG. 6 illustrates a process of deriving a dynamic model parameter for each layer of an auto encoder according to an embodiment of the present invention;

Referring to FIG. 6, an encoding network corresponding to an encoding device and a decoding network corresponding to a decoding device are illustrated. The encoding network may be composed of b+1 layers, and the decoding network may be composed of L-b−1 layers.

Referring to FIG. 6, a dynamic model parameter generation network corresponding to each of layers constituting an encoding network and a decoding network may be defined as Gi. Here, i means the index of the layer. As for the model generation parameter, FC, CNN, etc. can be used in the form of deep-learning.

Referring to FIG. 6, for layers constituting the encoding network and the decoding network including the input layer, the feature of the current layer i x⁽ⁱ⁾ from the feature x⁽ⁱ⁻¹⁾ of the previous layer i−1. The dynamic model parameter {w⁽ⁱ⁾, b⁽ⁱ⁾} required to calculate) can be determined.

In FIG. 6, the encoding network encodes and quantizes the input signal, and the decoding network decodes the quantized result. In this case, the dynamic model parameters used in the encoding network and the decoding network may be determined through a separate network (dynamic model parameter generation network) according to feature of each of the layers constituting the encoding network and the decoding network.

As shown in FIG. 6, a dynamic model parameter of a layer may be determined from a dynamic model parameter generation network for each of all layers constituting an encoding network and a decoding network. In FIG. 6, the dynamic model parameters {w⁽¹⁾, b⁽¹⁾} determined in layer 0 are used to extract the features of layer 1.

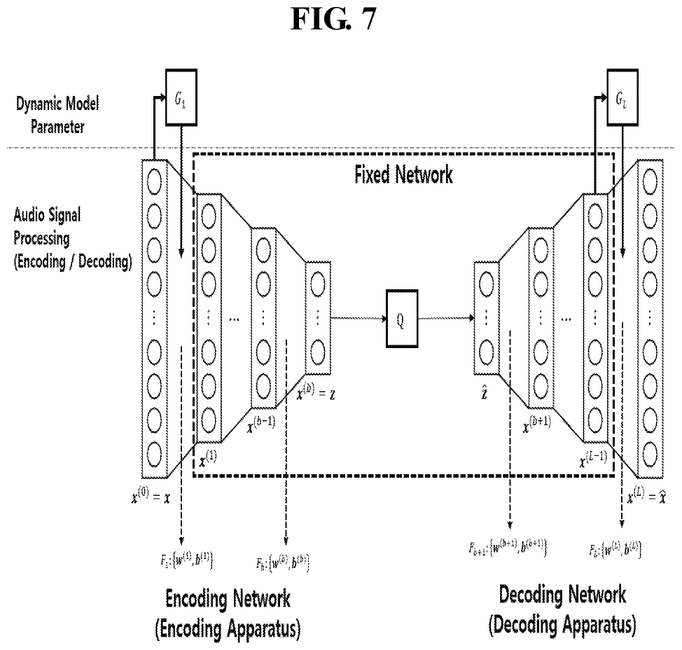

FIG. 7 illustrates a process of deriving dynamic model parameters for a specific layer of an auto encoder according to another embodiment of the present invention.

As shown in FIG. 7, in order to reduce complexity, dynamic model parameters may be generated only for a specific layer in addition to generating dynamic model parameters for all layers of an encoding network and a decoding network.

In FIG. 7, dynamic model parameters {w⁽ⁱ⁾, b⁽ⁱ⁾|i=1, L} for layer 1, which is an input layer of an encoding network, and layer L, which is an output layer of a decoding network, can be dynamically determined according to the feature of the previous layer, respectively. However, the dynamic model parameters {w⁽ⁱ⁾, b⁽ⁱ⁾|i=2, L−1} for other layers except for the input layer of the encoding network and the output layer of the decoding network may be static model parameter.

In FIG. 7, layers 2 to L−1 are set as a static network, but the present invention is not limited thereto. Layers included in the static network covering the coding and decoding networks may be differently determined according to a loss function including a signal quality and a compression rate according to coding and decoding and a quantization method.

Consequently, according to an embodiment of the present invention, by deriving dynamic model parameters for layers constituting an encoding network and a decoding network, it is possible to expect an effect of improving signal reconstruction quality and compression rate according to encoding and decoding.

According to an embodiment of the present invention, by applying an auto encoder to an audio signal to process an audio signal, an audio signal can be efficiently encoded and restored close to an original signal.

According to an embodiment of the present invention, an audio signal can be effectively processed by generating a dynamic model parameter generation network for each of layers constituting an encoding network and a decoding network of an auto encoder.

The units and/or modules described herein may be implemented using hardware components and software components. For example, the hardware components may include microphones, amplifiers, band pass filters, audio to digital convertors, and processing devices. A processing device may be implemented using one or more hardware device configured to carry out and/or execute program code by performing arithmetical, logical, and input/output operations. The processing device(s) may include a processor, a controller and an arithmetic logic unit, a digital signal processor, a microcomputer, a field programmable gate array, a programmable logic unit, a microprocessor or any other device capable of responding to and executing instructions in a defined manner. The processing device may run an operating system (OS) and one or more software applications that run on the OS. The processing device also may access, store, manipulate, process, and create data in response to execution of the software. For purpose of simplicity, the description of a processing device is used as singular; however, one skilled in the art will appreciated that a processing device may include multiple processing elements and multiple types of processing elements. For example, a processing device may include multiple processors or a processor and a controller. In addition, different processing configurations are possible, such as parallel processors.

The software may include a computer program, a piece of code, an instruction, or some combination thereof, to independently or collectively instruct and/or configure the processing device to operate as desired, thereby transforming the processing device into a special purpose processor. Software and data may be embodied permanently or temporarily in any type of machine, component, physical or virtual equipment, computer storage medium or device, or in a propagated signal wave capable of providing instructions or data to or being interpreted by the processing device. The software also may be distributed over network coupled computer systems so that the software is stored and executed in a distributed fashion. The software and data may be stored by one or more non-transitory computer readable recording mediums.

The methods according to the above-described embodiments may be recorded in non-transitory computer-readable media including program instructions to implement various operations of the above-described embodiments. The media may also include, alone or in combination with the program instructions, data files, data structures, and the like. The program instructions recorded on the media may be those specially designed and constructed for the purposes of embodiments, or they may be of the kind well-known and available to those having skill in the computer software arts. Examples of non-transitory computer-readable media include magnetic media such as hard disks, floppy disks, and magnetic tape; optical media such as CD-ROM discs, DVDs, and/or Blue-ray discs; magneto-optical media such as optical discs; and hardware devices that are specially configured to store and perform program instructions, such as read-only memory (ROM), random access memory (RAM), flash memory (e.g., USB flash drives, memory cards, memory sticks, etc.), and the like. Examples of program instructions include both machine code, such as produced by a compiler, and files containing higher level code that may be executed by the computer using an interpreter. The above-described devices may be configured to act as one or more software modules in order to perform the operations of the above-described embodiments, or vice versa.

A number of embodiments have been described above. Nevertheless, it should be understood that various modifications may be made to these embodiments. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claim.

What is claimed is:

1. An audio encoding method using a dynamic model parameter, comprising:
reducing a dimension of audio signal using an encoding network;
outputting a code corresponding to audio signal of a final level whose the dimension is reduced; and
quantizing the code,
wherein the outputting the code reduces the dimension of the audio signal corresponding to a plurality of layers of N level by using a dynamic model parameter of each of the layers of the encoding network.

2. The method of claim 1, wherein the dynamic model parameter is generated for the layers corresponding to N−1 level in all N level.

3. The method of claim 1, wherein the dynamic model parameter is determined in a dynamic model parameter generation network independent of the encoding network.

4. The method of claim 1, wherein the dynamic model parameter is determined based on a feature of a previous level to determine the feature of a next level.

5. The method of claim 1, wherein the encoding network determines a feature for the audio signal of a next level using a feature for the audio signal of a previous level and the dynamic model parameter of the next level,
wherein the feature for the audio signal of the next level is a signal whose dimension is reduced than the feature for the audio signal of the previous level.

6. An audio decoding method using a dynamic model parameter, comprising:
receiving a quantized code of an audio signal corresponding to a reduced dimension;
extending the dimension of the audio signal in a decoding network by using the code of the audio signal;
outputting the audio signal of a final level with an expanded dimension in the decoding network,
wherein the extending the dimension of the audio signal extends the dimension of the audio signal corresponding to the layer of N levels by using a dynamic model parameter of each of the levels of the decoding network.

7. The method of claim 6, wherein the dynamic model parameter is generated for the layers corresponding to N−1 level in all N level.

8. The method of claim 6, wherein the dynamic model parameter is determined in a dynamic model parameter generation network independent of the encoding network.

9. The method of claim 6, wherein the dynamic model parameter is determined based on a feature of a previous level to determine the feature of a next level.

10. The method of claim 6, wherein the decoding network determines a feature for the audio signal of a next level using a feature for the audio signal of a previous level and the dynamic model parameter of the next level,
wherein the feature for the audio signal of the next level is a signal whose dimension is extended than the feature for the audio signal of the previous level.

11. An audio encoding method using a dynamic model parameter, comprising:
reducing a dimension of audio signal using an encoding network;
outputting a code corresponding to audio signal of a final level whose the dimension is reduced; and
quantizing the code,
wherein the outputting the code reduces the dimension of the audio signal corresponding to a plurality of layers of N level by using a dynamic model parameter of at least one of specific layer among the layers of the encoding network.

12. The method of claim 11, wherein the outputting the code reduces the dimension of the audio signal is reduced using dynamic model parameters at the specific level of the encoding network, and reduces the dimension of the audio signal using static dynamic model parameters at a remaining levels except for the specific level among all levels of the encoding network.

13. The method of claim 11, wherein the dynamic model parameter is determined in a dynamic model parameter generation network independent of the encoding network.

14. The method of claim 11, wherein the dynamic model parameter is determined based on a feature of a previous level to determine the feature of a next level.

15. The method of claim 11, wherein the encoding network determines a feature for the audio signal of a next level using a feature for the audio signal of a previous level and the dynamic model parameter of the next level,
wherein the feature for the audio signal of the next level is a signal whose dimension is reduced than the feature for the audio signal of the previous level.
